(19) United States
(12) Patent Application Publication
(10) Pub. No.: US 2007/0229088 A1
(43) Pub. Date: Oct. 4, 2007

(54) FAILURE DISPLAY UNIT AND DISK DRIVE DEVICE WITH FAILURE DISPLAY FUNCTION

(75) Inventor: Jun SUZUKI, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: NEC CORPORATION, Tokyo (JP)

(21) Appl. No.: 11/691,109

(22) Filed: Mar. 26, 2007

(30) Foreign Application Priority Data
Mar. 31, 2006 (JP) 2006-097284

(51) Int. Cl. G01R 31/00

(52) U.S. Cl. 324/500

(57) ABSTRACT

A failure display unit with a simple structure, that enables a user to recognize the occurrence condition or occurrence history of failures in a device by sight even when the device is in an inoperative state, is provided.

The failure display unit includes a heat-sensitive material which changes its color irreversibly according to a temperature, a heater provided near the heat-sensitive material for generating heat when power applied, a power supply circuit for supplying power to the heater, and a casing in which the heat-sensitive material and the heater are laid, wherein the relationships between the types of failures and the discolorations of the heat-sensitive material is predetermined.

### BACKGROUND OF THE INVENTION

1. Field of the Invention

The present invention relates to a failure display unit and a disk drive device with a failure display function.

2. Description of the Related Art

Some devices incorporating microcomputers execute self-diagnosis by the microcomputer to perform operation failure detection or operation failure determination of the device with a previously installed firmware. When the microcomputer performs the self-diagnosis of the device and detects failures, it sends the information of the occurrence condition or occurrence history of the failures to a host device such as a host computer connected to the device for display or stores the information in a nonvolatile memory included in the device.

The information of the occurrence condition or occurrence history of the failures is stored in the nonvolatile memory in the device as a log data. Therefore, while the host computer is connected electrically to the device, the host computer can read the information of the occurrence condition or occurrence history of the failures from the nonvolatile memory in the device and can display them. Accordingly, an operator or a user can recognize the occurrence condition of failures by viewing the display on the host computer. However, if the operator or the user once release displaying of those occurrence condition or occurrence history of the failures displayed on the host computer, a host computer needs to access a non-volatile memory inside the device and read out those information again in order to confirm those information again. In other words, if an electrical connection between the device and the host computer is released, the operator or the user is no longer able to recognize the occurrence condition or occurrence history of the failures or the like, and this is inconvenient for the standalone device.

Especially, it is likely to have the above-mentioned problem for a disk array system that is operated with a plurality of disk drive devices mounted on a single casing. In the disk array system under its usual operating conditions, a plurality of disk drive devices are connected with a host computer and receive power supply. In the case of maintenance, however, the disk drive devices may be disconnected from the host computer so that the function of the disk drive devices stops, and the plurality of disk drive devices may be collectively retrieved from the casing. In such a case, the host computer cannot display the information of the occurrence condition of the failures even if there was a failed disk drive device because the disk drive devices are disconnected from the host computer. Also, it is difficult for an operator or a user to distinguish the failed disk drive device simply by sight because all the disk drive devices are in the same shape and the same size each other. As such, it causes a problem in managing a disk drive device such that a failed disk drive device is mounted again without fixed.

Japanese Patent Laid-Open No. 2002-109871 discloses a system that enables a history related to a device to be recognized even if the device stops its function. Specifically, it discloses a magnetic disk storage device for storing a status such as data storage error or the like on a heat-sensitive material by changing the color of the heat-sensitive material in a sheet form attached to the disk drive device. The magnetic disk storage device, however, needs to drive and control heating members with wiring patterns appropriate for generating a character, a graphic and the like and store information on the heat-sensitive material by using the character and the graphic in order to store complicated information on the heat-sensitive material. Therefore, it has a problem in that it is hard to be applied to a device with a simple structure.

Japanese Utility Model Laid-Open No. 6-74973 discloses a failure display device including a determining circuit for detecting a failure current, a surface heater for heating with the output from the determining circuit, and a display member for displaying the failure occurrence by changing its color as heated by the surface heater. As the failure display device, however, displays only the presence of the failure, it has a problem in that a user cannot recognize the type of the failure.

As the heat-sensitive material that changes its color irreversibly as it detects rise in temperature, a thermo tape, a thermo seal, a thermo label, a thermo seat and the like, in a form of film, which are applied with a paint that changes its color according to the temperature are well-known. A heat-sensitive material which records the maximal temperature by changing its color irreversibly according to a given temperature is also commercially available.

### SUMMARY OF THE INVENTION

An exemplary feature of the invention is to provide a failure display unit and a disk drive device with a failure display function with a simple structure that enables a user or an operator to recognize the occurrence condition or occurrence history of failures in the device by sight even when the device is in an inoperative state.

The failure display unit according to the present invention includes a heat-sensitive material which changes its color irreversibly according to a temperature; a heater provided near the heat-sensitive material for generating heat when power applied; a power supply circuit for supplying power to the heater; and a casing in which the heat-sensitive material and the heater are laid; wherein the relationships between the types of failures and the discolorations of the heat-sensitive material is predetermined.

The failure display unit according to the present invention includes a plurality of heat-sensitive materials that change their colors irreversibly in response to the detection of a rise in temperature; a plurality of heaters respectively provided near the plurality of heat-sensitive materials for generating heat when power applied; a power supply circuit for supplying power to each of the heaters; and a casing on which each of the plurality of heat-sensitive materials and each of the heaters are laid; wherein the relationships between the types of failures and the combinations of heaters is predetermined.

The disk drive device with a failure display function according to the present invention includes a failure display unit having: a heat-sensitive material which changes its color irreversibly according to a temperature; a heater provided near the heat-sensitive material for generating heat when power applied; a power supply circuit for supplying power to the heater; and a casing in which the heat-sensitive material and the heater are laid; wherein a relationship between the type of failure and the change of color of the heat-sensitive material is predetermined; and an operation failure determining circuit for controlling the power supply circuit to supply power to the heater for a power-supplying time set corresponding to the type of the failure when an operation failure in a hard disk drive mechanism is detected.

The disk drive device with a failure display function according to the present invention includes a failure display unit having: a plurality of heat-sensitive materials that change their colors irreversibly in response to the detection of a rise in temperature; a plurality of heaters respectively provided near the plurality of heat-sensitive materials for generating heat when power applied; a power supply circuit for supplying power to each of the heaters; and a casing on which each of the heat-sensitive material and each of the heaters are laid; wherein a relationship between the type of failure and the combination of heaters is predetermined; and an operation failure determining circuit for controlling the power supply circuit to supply power only to a combination of heaters set corresponding to the type of failure when an operation failure in a hard disk drive mechanism is detected.

With the above-mentioned configuration, the failure display unit and the disk drive device with a failure display function according to the present invention can store the information of the occurrence condition or occurrence history of failures and the like in various devices such as a disk drive device with a simple operation of only heating the heater. This eliminates the need for heating members with complicated wiring pattern and its controlling device. Therefore, the present invention has an advantage in providing a failure display function and a disk drive device with a failure display unit in a simple structure for enabling a user or an operator to easily recognize the occurrence condition or the occurrence history of the failures by sight even if the device is in an inoperable state.

### BRIEF DESCRIPTION OF THE DRAWINGS

The above and other exemplary features, and advantages of the present invention will become more apparent from the following detailed description when taken in conjunction with the accompanying drawings wherein:

FIG. 1 is a diagram showing a simplified configuration of a failure display unit according to a first exemplary embodiment of the present invention;

FIG. 2A is a diagram showing a simplified configuration of a failure display unit according to a second exemplary embodiment of the present invention;

FIG. 2B is a diagram showing a simplified configuration of a disk drive device with a failure display function provided with the failure display unit shown in FIG. 2A;

FIG. 3 is a conceptual diagram showing an example of a display form for displaying a type of failure due to a change of color of a plurality of heat-sensitive materials;

FIG. 4 is a block diagram showing a simplified configuration of a disk drive device mounted with a failure display unit according to the first or the second exemplary embodiment;

FIG. 5 is a block diagram showing a detailed configuration of operation failure determining means in FIG. 4;

FIG. 6 is a diagram showing a configuration of a first table and a second table;

FIG. 7 is a diagram schematically showing a configuration of a failure display unit, a power supply controlling part and a power supply means according to the first exemplary embodiment; and

FIG. 8 is a diagram schematically showing a configuration of a failure display unit, a power supply controlling part and a power supply means according to the second exemplary embodiment.

### DETAILED DESCRIPTION OF THE EXEMPLARY EMBODIMENTS

The present invention will be described below based on the exemplary embodiments.

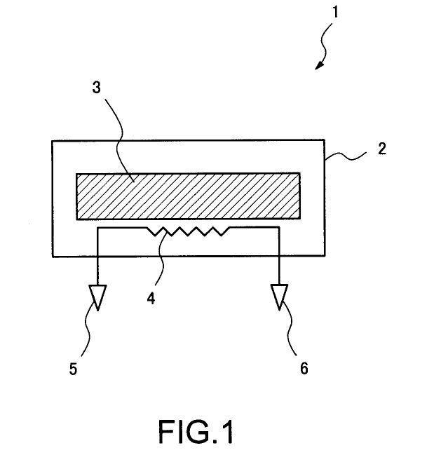

FIG. 1 is a diagram showing a simplified configuration of a failure display unit according to a first exemplary embodiment of the present invention. As shown in FIG. 1, the failure display unit 1 includes a hollow flat rectangle casing 2, a heat-sensitive materials 3 laid on the casing 2, a heater 4 provided on the casing 2 close to the heat-sensitive materials 3 which includes electrically heated wires or the like that generate heat if the power is applied, and a first and a second power supply terminals 5 and 6 for supplying power to the heater 4.

As the heat-sensitive materials 3, for example, a thermo tape, a thermo seal, a thermo label, a thermo seat and the like in a form of a film applied with a paint that changes color in response to the detection of a rise in temperature are used.

The heat-sensitive paints include that with reversibility for returning to its original color when it is cooled to the normal heat after being heated, and that with irreversibly that does not return to its original color even when it is cooled to the normal heat. They also include a paint which changes its color when it is heated more than a certain temperature and keeps the color even if the temperature rises further, or further changes its color as it is heated. In this embodiment, a paint that irreversibly changes its color as it is heated is used.

For example, a thermo tape that changes its color in four stages of black, as an initial color, reddish brown, green, blue and dark blue in order is known. As the color changes according to the temperature, the color changes from black, an initial color, to any of reddish brown, green, blue, dark blue in response to rise in temperature, but the tape does not change its color of reddish brown back to black, the initial color, even if the temperature dropped, or the tape does not change its color of green back to reddish brown that is corresponding to a lower temperature range.

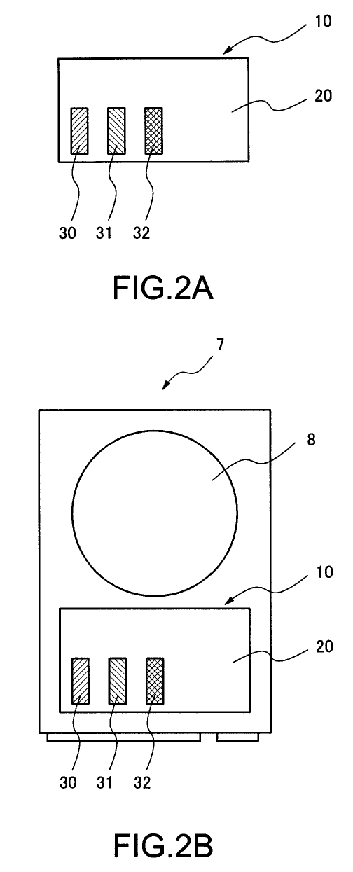

FIG. 2A is a diagram showing a simplified configuration of a failure display unit 10 according to a second exemplary embodiment of the present invention. FIG. 2B is a diagram showing a simplified configuration of a disk drive device with a failure display function 7 provided with the failure display unit 10.

The failure display unit 10 includes a plurality of heat-sensitive materials 30, 31 and 32 and a casing 20. A plurality of heat-sensitive materials 30, 31 and 32 are arranged apart from each other. The failure display unit 10 also includes heaters provide for each of the heat-sensitive materials 30, 31 and 32, and power supply terminals provided for each heater for supplying power to each heater. The configuration is the same as that in FIG. 1 except that the heat-sensitive material 3 and the heater 4 and the first and the second power supply terminals 5 and 6 are arranged in a row, thus, the detailed configuration will be omitted from the description.

The disk drive device with a failure display function 7 includes a failure display unit 10, a hard disk drive mechanism unit 8 and a controlling unit (not shown). Although the disk drive device with a failure display function 7 which includes the failure display unit 10 is shown in FIG. 2A here, it may include the failure display unit 1 shown in FIG. 1.

The failure display unit 10 shown in FIG. 2A uses materials that change to different colors each other as the heat-sensitive materials 30, 31 and 32 so that a user can clearly distinguish the discolored heat-sensitive materials 30, 31 and 32. However, the colors after discoloration of the heat-sensitive materials 30, 31, 32 do not always have to be different each other. This is because it is possible to specify the relationship between the presence of discoloration or the combination of the presence of discoloration of each heat-sensitive materials 30, 31, 32 and the failure history by sticking a sticker corresponding to instructions in casing 20, or giving relief or sculpture-like stamping to casing 20 itself by a forming process of a casing 20 (detailed description will be made later).

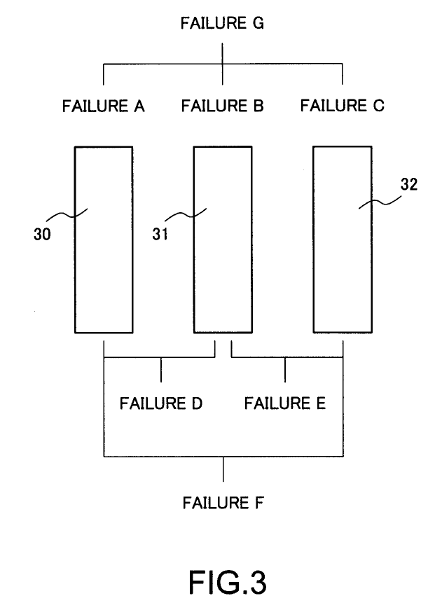

FIG. 3 is an exemplified diagram showing the relationship between discolorations or combinations of discolorations of each heat-sensitive materials 30, 31, 32 and types of failures by sticking stickers or stamping on the failure display unit 10 shown in FIG. 2A. Although types of failures are described by symbols with “failure A”-“failure G”, the details of failures may be indicated specifically by sticking stickers or stamping on the casing 20.

As the heat-sensitive materials 30, 31, 32 shown in FIG. 3, a material that changes its color once in response to the detection of a rise in temperature is used. In the example shown in FIG. 3, a state in which only the heat-sensitive material 30 changed its color corresponds to “failure A”, a state in which only the heat-sensitive material 31 changed its color corresponds to “failure B”, and a state in which only the heat-sensitive material 32 corresponds to “failure C”. Also, a state in which only the heat-sensitive materials 30 and 31 simultaneously changed their colors corresponds to “failure D”, and a state in which only the heat-sensitive materials 31 and 32 simultaneously changed their colors corresponds to “failure E”, and a state in which only the heat-sensitive materials 30 and 32 simultaneously changed their colors corresponds to “failure G”. Further, a state in which all the heat-sensitive materials 30, 31, 32 simultaneously changed their colors corresponds to “failure F”. Therefore, as shown in FIG. 3, the failure display unit 10 with three heat-sensitive materials 30, 31, 32 which change their colors once can represent information by 2³=8 in all, i.e., by three bits, including a state in which no heat-sensitive material changed its color, that means no failure.

That is, as each heat-sensitive material can represent information by only its color changing, it can represent information by one bit. In other words, if the failure display unit 10 is arranged with N heat-sensitive materials separated from each other, it can represent information by N bits.

As mentioned above, if heat-sensitive materials 3 that changes its color by four stages from black, an initial color, to reddish brown, green, blue, and dark blue according to a rise in temperature is used and arranged in three lines as shown in FIG. 3, information of 5³=125 in all including a state of no failure can be represented theoretically. In this case, however, it is quite difficult to indicate all the relationships between a color change or a combination of color changes of three heat-sensitive materials and a failure condition by putting notices on the casing 20 because of the limitation of spaces, thus, an instruction manual or the like is required to be attached separately. Therefore, it is actually desirable to use a heat-sensitive material 3 that irreversibly changes its color by some stages according to a rise in temperature as shown in FIG. 1, or some heat-sensitive materials 30, 31, 32 that change their color only once in response to the detection of a rise in temperature as shown in FIG. 3.

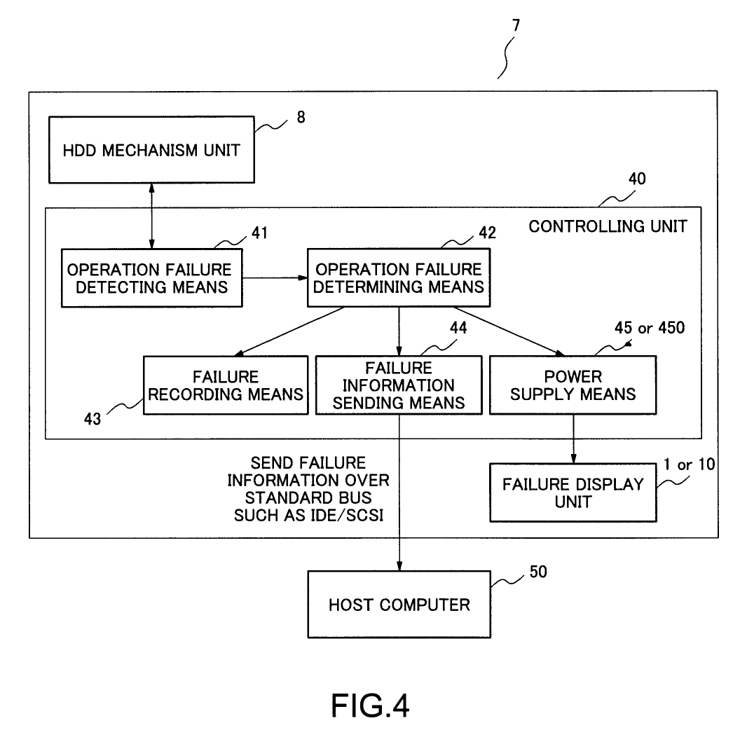

FIG. 4 is a block diagram showing a simplified configuration of a disk drive device 7 mounted with a failure display unit 1 shown in FIG. 1 or a failure display unit 10 shown in FIG. 2.

The disk drive device 7 includes a hard disk drive mechanism unit 8, a controlling unit 40, a failure display unit 1 or a failure display unit 10. The controlling unit 40 includes operation failure detecting means 41, operation failure determining means 42, failure recording means 43, failure information sending means 44 and power supply means 45 corresponding to failure display unit 1 or power supply means 450 corresponding to the failure display unit 10.

The hard disk drive mechanism unit 8, operation failure detecting means 41, operation failure determining means 42, failure recording means 43, failure information sending means 44 are well-known means. As described in the section of Description of the Related Art, the operation failure detecting means 41 and the operation failure determining means 42 are implemented by a microcomputer (hereinafter simply referred to a CPU (Central Processing Unit)), not shown, incorporated in the disk drive device 7 and firmware installed in a ROM (Read Only Memory) in the CPU.

The operation failure detecting means 41 detects a failure occurs or not in the hard disk drive mechanism unit 8 which includes a spindle motor or a voice coil motor and their peripheral circuit. Alternatively, it detects a failure which may occur in writing or reading data by the hard disk drive mechanism unit 8 by parity check or the like.

If the operation failure determining means 42 receives a notice of detecting a failure from the operation failure detecting means 41, it determines the type of the failure and informs it to the failure information sending means 44. The failure information sending means 44 which consists of a bus such as IDE (Integrated Drive Electronics) or a SCSI (Small Computer System Interface) and the like and an interface circuit, sends failure information of the occurrence of failure and the type of the failure based on the information from the operation failure determining means 42 to a host device such as the host computer 20.

Consequently, the occurrence of the failure and the type of the failure are displayed on a display of the host device. The operation failure determining means 42 also sends the occurrence of the failure and the type of the failure be stored to the failure recording means 43 which consists of a nonvolatile memory and the like included in the disk drive device 7.

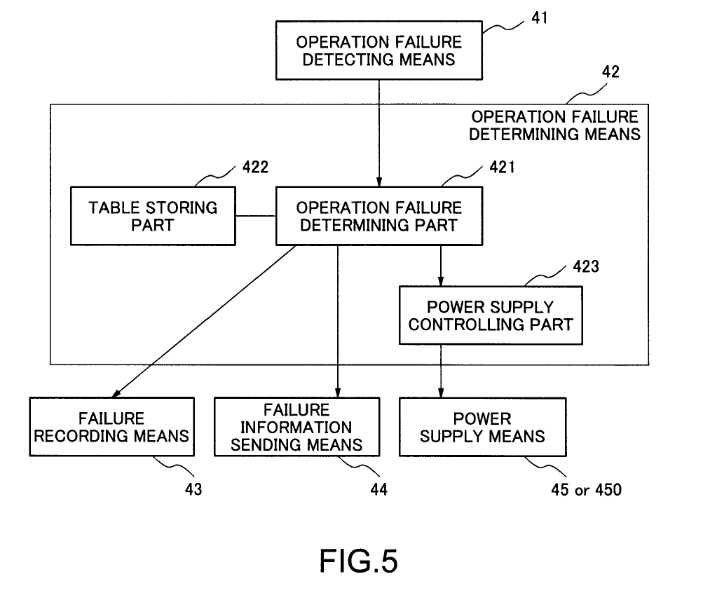

FIG. 5 is a block diagram showing a detailed configuration of operation failure determining means 42. As shown in FIG. 5, the operation failure determining means 42 includes an operation failure determining part 421, a table storing part 422, and a power supply controlling part 423. The operation determining part 421 determines the type of the failure when it receives the information of the detection of a failure from the operation failure detecting means 41. Then, it reads out a power-supplying condition for the heater corresponding to the type of the failure from a first table or a second table stored in a table storing part 422 and informs it to the power supply controlling part 423.

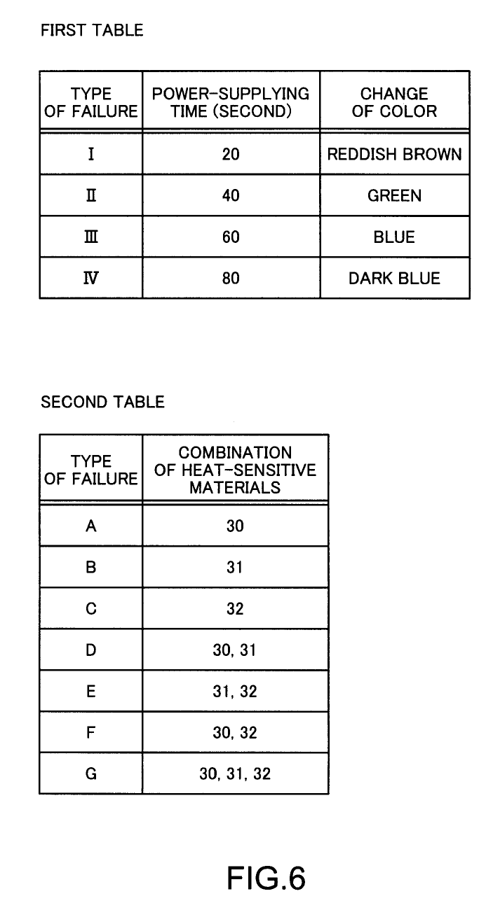

FIG. 6 is a diagram showing a configuration of the first table and the second table. The first table stores in advance the relationships between the types of failures and power-supplying times corresponding to each type of failures. The second table stores in advance the relationships between the types of failures and combinations of heat-sensitive material corresponding to each type of failures. The first table and the second table are used in distinguishing the types of failures to be described later.

Referring to FIGS. 5 and 6, a method for distinguishing the types of failures occurred in the disk drive device 7 will be described.

First, a method for distinguishing the types of failures when the failure display unit 1 is mounted on the disk drive device 7 is described. In the case that the failure display unit 1 shown in FIG. 1 is mounted on the disk drive device 7, the operation failure determining means 42 has the first table in the table storing part 422.

When the operation failure determining part 421 provided in the operation failure determining means 42 has received a failure detecting signal from the operation failure detecting means 41, it determines the type of the failure. Then, it reads out a power-supplying time corresponding to the determined type of the failure from the first table, and informs it to the power supply controlling part 423.

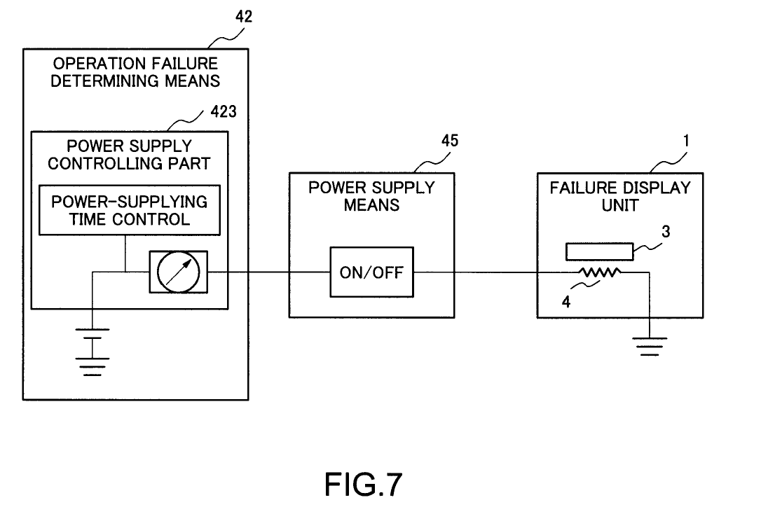

FIG. 7 is a diagram schematically showing a configuration of the power supply controlling part 423, the power supply means 45, and the failure display unit 1. The power supply controlling part 423 controls the power supply means 45 to supply power to the failure display unit 1 for the power-supplying time received from the operation failure determining part 421. The power supply means 45 is a simply structured switching circuit for performing ON/OFF control according to an instruction from the power supply controlling part 423. Specifically, as the power supply controlling part 423 receives a power-supplying time from the operation failure determining part 421, it instructs the power supply means 45 to switch to the state of ON and starts measuring the elapsed time. When the measured elapsed time reaches the power-supplying time received from the operation failure determining part 421, the power supply controlling part 423 instructs the power supply means 45 to switch back to the state of OFF.

Consequently, the amount of power corresponding to this type of the failure is supplied to the heater 4 for heating the heat-sensitive material 3 and the heat-sensitive material 3 changes its color to that corresponding to the type of failure. For example, if the operation failure determining part 421 determines the type of the failure as “II”, the power supply controlling part 423 controls the power supply means 45 to energize the failure display unit 1 for 40 seconds. The heater 4 of the failure display unit 1 is energized for 40 seconds, and the heat-sensitive material 3 changes its color to green. The operator can recognize that the failure “II” occurs by viewing the heat-sensitive material 3 changed its color to green.

It is a matter of course that the power supply controlling part 423 can adjust the amount of power, i.e., a heat value, to supply by modulating an applied voltage with keeping the power-supplying time constant without regarding of the type of the failure. Note that, the power supply controlling part 423 preferably has simpler configuration if it is adapted to control the heat voltage by modulating the power-supplying time than it is adapted to control the heat voltage by modulating an applied voltage. It is also convenient for the power supply controlling part 423 to control the heat value by modulating the power-supplying time because it can use the driving power (voltage) for the disk drive device 7 only by adjusting the power-supplying time.

Now, a method for distinguishing the types of failures when the failure display unit 10 is mounted on the disk drive device 7 shown in FIG. 2A is described. In the case that the failure display unit 10 shown in FIG. 2A is mounted on the disk drive device 7, the operation failure determining means 42 has the second table in the table storing part 422.

As the operation failure determining part 421 provided in the operation failure determining means 42 receives a failure detecting signal from the operation failure detecting means 41, it determines the type of the failure. Then, it reads out a combination of heat-sensitive materials corresponding to the determined type of the failure from the second table, and informs it to the power supply controlling part 423.

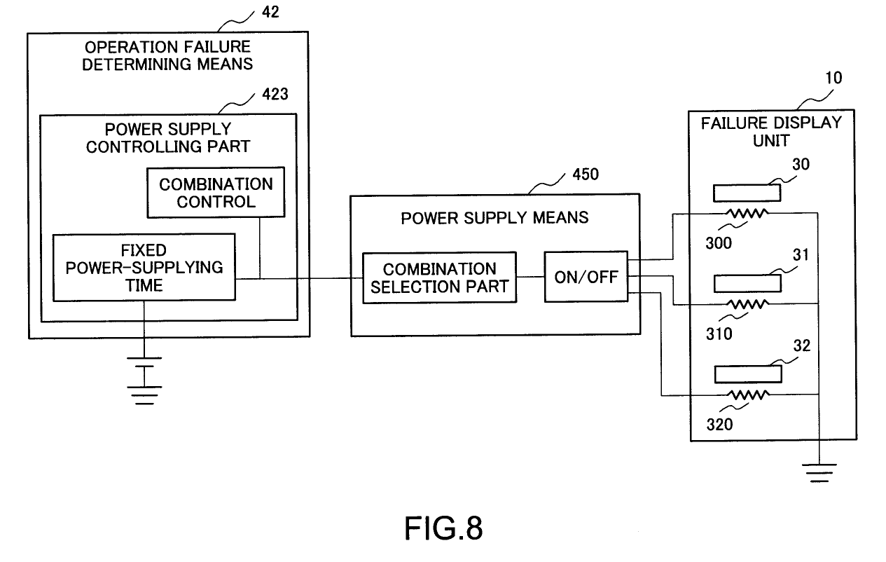

FIG. 8 is a diagram schematically showing the configuration of the power supply controlling part 423, the power supply means 450, and the failure display unit 10. The power supply controlling part 423 controls the power supply means 450 to supply power only to the heater for heating the heat-sensitive materials respectively corresponding to the combination received from the operation failure determining part 421. The power supply means 450 is a switching circuit for selecting heaters which heat the combination of the heat-sensitive materials informed from the power supply controlling part 423, and for performing ON/OFF control to supply power only to the heaters. Specifically, as the power supply controlling part 423 receives a combination of the heat-sensitive materials from the operation failure determining part 421, it switches the power supply means 450 to the state of ON to energize the heaters according to the combination, and starts measuring the elapsed time. When the elapsed time reaches the time required for changing the color of the heat-sensitive materials, the power supply controlling part 423 switches the power supply means 450 back to the state of OFF.

Consequently, only the heaters corresponding to the type of the failure among the heaters 300, 310, 320 for heating the heat-sensitive materials 30, 31, 32 respectively are energized so that only the heat-sensitive materials corresponding to the type of the failure change their color. For example, in the case where the relationships between the types of the failures and the heat-sensitive materials 30, 31, 32 to be changed their colors is like that shown in FIG. 3, if the type of the failure determined by the operation failure determining means 42 is the “failure A”, the power supply means 450 selectively supplies power only to the heater 300 for heating the heat-sensitive material 30 and changes the color of the heat-sensitive material 30. Also, if the type of the failure determined by the operation failure determining means 42 is the “failure D”, the power supply means 450 selectively supplies power to the heater 300, 310 for heating the heat-sensitive material 30, 31 and changes the color of the heat-sensitive material 30, 31. The operator can recognize the type of the failure according to the type of heat-sensitive materials whose colors have changed.

Note that, even when a plurality of heat-sensitive materials is provided, not all the types of failures are displayed by indicating all the combinations of the discolorations. Therefore, when the operation failure determining means 42 has the function to classify precisely and determine the types of failures, it may store the types of failures by the change with the color of the heat-sensitive material only when a failure which can cause a critical damage in future occurs.

As mentioned above, the failure display unit 1 with a heat-sensitive material 3 that changes its color according to the temperature is implemented on the disk drive device 7 to change the color of the heat-sensitive material 3 corresponding to the type of the faire by the heater 4. Alternatively, the failure display unit 10 with a plurality of heat-sensitive materials 30, 31, 32 is implemented on the disk drive device 7 to change the color of the heat-sensitive materials corresponding to the type of the failure by the heaters 300, 310, 320. Consequently, the types of failures occurred to the disk drive device 7 and their history can be stored on the heat-sensitive materials irreversibly and statically.

With such a configuration, a user or an operator can easily recognize the occurrence of failures or their history by viewing the state of the heat-sensitive materials provided on the failure display unit 1 or the failure display unit 10, even if the disk drive device 7 is out of order due to failures, or if the log of the failures recording means 43 cannot be read out from the host device as the disk drive device 7 is removed from the casing of the disk array system.

Therefore, especially in disk array system that operates with mounted a plurality of disk drive device 7 in a single casing, in the case that the disk drive devices 7 having the same shape and the same size each other are removed from the casing for maintenance or the like, a user or an operator can easily and correctly recognize the presence of the failures occurred in each disk drive device 7. Therefore, the present invention has an advantage of thoroughly eliminating a problem in that the failed disk drive device 7 is mounted again without fixed.

Also, as the occurrence conditions of failures or their history can be stored in the heat-sensitive material with a simple operation such as only to change the color of the heat-sensitive material as a voltage is applied to the power supply terminal to heat the heater, heating members with complicated wiring patterns and their controlling devices can be unnecessary. Accordingly, a failure display unit and a disk drive device with such a failure display unit that enables the occurrence conditions of failures or their history can be provided with a simple configuration inexpensively.

While this invention has been described in connection with certain exemplary embodiments, it is to be understood that the subject matter encompassed by way of this invention is not to be limited to those specific embodiments. On the contrary, it is intended for the subject matter of the invention to include all alternative, update, and equivalents as can be included within the spirit and scope of the following claims. Further, the inventers' invention is to retain all equivalents of the claimed invention even if the claims are amended during prosecution.

What is claimed is:

1. A failure display unit comprising:
a heat-sensitive material which changes its color irreversibly according to a temperature;
a heater provided near said heat-sensitive material for generating heat when power applied;
a power supply circuit for supplying power to said heater; and
a casing in which said heat-sensitive material and said heater are laid;
wherein the relationships between the types of failures and the discolorations of said heat-sensitive material is predetermined.

2. A failure display unit comprising:
a plurality of heat-sensitive materials that change their colors irreversibly in response to the detection of a rise in temperature;
a plurality of heaters respectively provided near said plurality of heat-sensitive materials for generating heat when power applied;
a power supply circuit for supplying power to each of said heaters; and
a casing on which each of said plurality of heat-sensitive materials and each of said heaters are laid;
wherein the relationships between the types of failures and the combinations of heaters is predetermined.

3. The failure display unit according to claim 2, wherein said plurality of heat-sensitive materials changes their colors to different colors each other.

4. A disk drive device with a failure display function comprising:
a failure display unit including: a heat-sensitive material which changes its color irreversibly according to a temperature; a heater provided near said heat-sensitive material for generating heat when power applied; a power supply circuit for supplying power to said heater; and a casing in which said heat-sensitive material and said heater are laid; wherein a relationship between the type of failure and the change of color of said heat-sensitive material is predetermined; and
an operation failure determining circuit for controlling said power supply circuit to supply power to said heater for a power-supplying time set corresponding to the type of the failure when an operation failure in a hard disk drive mechanism is detected.

5. A disk drive device with a failure display function comprising:
a failure display unit including: a plurality of heat-sensitive materials that change their colors irreversibly in response to the detection of a rise in temperature; a plurality of heaters respectively provided near said plurality of heat-sensitive materials for generating heat when power applied; a power supply circuit for supplying power to each of said heaters; and a casing on which each of said heat-sensitive material and each of said heaters are laid; wherein a relationship between the type of failure and the combination of heaters is predetermined; and
an operation failure determining circuit for controlling said power supply circuit to supply power only to a combination of heaters set corresponding to the type of failure when an operation failure in a hard disk drive mechanism is detected.

6. The disk drive device with a failure display function according to claim 5, wherein said plurality of heat-sensitive materials change their colors to different colors each other.
